(19) United States
(12) Patent Application Publication
(10) Pub. No.: US 2026/0344043 A1
(43) Pub. Date: Oct. 29, 2026

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 19/701,261

(22) Filed: Jun. 8, 2026

Related U.S. Application Data
(63) Continuation of application No. PCT/JP2024/030097, filed on Aug. 23, 2024.

(30) Foreign Application Priority Data
Dec. 14, 2023 (JP) 2023-211279

(51) Int. Cl. H10D 84/90; H10D 89/10

(52) U.S. Cl. CPC H10D 84/981; H10D 84/953; H10D 89/10

(57) ABSTRACT

A standard cell includes: an active region; an active region formed above the active region and overlapping with the active region in plan view; and power supply lines formed in a back wiring layer. A surface of each of nanosheets that is located on a first side which is one side in a second direction is exposed from a gate line. The power supply line is disposed at an end portion of the standard cell that is located on the first side. The power supply line is disposed at an end portion of the standard cell that is located on a second side which is the other side in the second direction.

### CROSS-REFERENCE TO RELATED APPLICATIONS

This is a continuation of International Application No. PCT/JP2024/030097 filed on Aug.23, 2024, which claims priority to Japanese Patent Application No. 2023-211279 filed on Dec. 14, 2023. The entire disclosures of these applications are incorporated by reference herein.

### BACKGROUND

The present disclosure relates to a semiconductor integrated circuit device including a standard cell (hereinafter also simply referred to as a cell as necessary) including a complementary FET (CFET).

A standard cell method is known as a method of forming a semiconductor integrated circuit on a semiconductor substrate. The standard cell method is a method of designing an LSI chip by preparing standard cells in advance including basic units (for example, an inverter, a latch, a flip-flop, a full adder, and others) with specific logic functions; then disposing the plurality of standard cells on the semiconductor substrate; and then connecting the standard cells by lines.

Further, the gate length of a transistor which is a basic component of an LSI has been reduced (scaling), thereby achieving an improved integration degree, a reduced operating voltage, and an improved operating speed. However, an off-current due to excessive scaling and a significant increase in power consumption due to the off-current have been concerned in recent years. To solve these problems, many studies have been conducted on a transistor with a three-dimensional structure developed from a traditional planar type structure. As one of the transistors with the three-dimensional structure, a nanosheet FET is attracting attention.

United States Patent Application Publication No. 2022/0123023 discloses a standard cell using a complementary FET (CFET) in which a P-type nanosheet transistor and an N-type nanosheet transistor are stacked on a substrate in order to reduce the area of a semiconductor integrated circuit device. United States Patent Application Publication No. 2022/0123023 discloses that a line is provided on a back surface just below the transistor and this line is connected with the source and drain of the transistor.

United States Patent Application Publication No. 2022/0246644 discloses a standard cell using a forksheet transistor in which a gate electrode in the nanosheet FET is formed into a fork shape in order to reduce the area of a semiconductor integrated circuit device. United States Patent Application Publication No. 2022/0246644 discloses the structure of a terminal cell in the standard cell using the forksheet transistor.

### SUMMARY

However, regarding a standard cell using a CFET, nothing specific has been considered yet about a layout structure of a standard cell using a forksheet transistor rather than a nanosheet transistor.

Regarding a standard cell using a CFET, an object of the present disclosure is to provide the layout of a semiconductor integrated circuit device including a standard cell using a forksheet transistor as a transistor.

An aspect of the present disclosure is directed to a semiconductor integrated circuit device including: a plurality of standard cells including a first standard cell, wherein the first standard cell includes a first active region forming a channel, a source, and a drain of a first transistor of a first conductivity type and including a first nanosheet extending in a first direction as the channel, a second active region formed above the first active region in a depth direction; overlapping with the first active region in plan view; forming a channel, a source, and a drain of a second transistor of a second conductivity type different from the first conductivity type; and including a second nanosheet extending in the first direction as the channel, a first gate line extending in a second direction perpendicular to the first direction and the depth direction and surrounding outer peripheries of the first nanosheet and the second nanosheet in the second direction and the depth direction, a first power supply line formed on a back surface side of the first transistor; extending in the first direction; and supplying a first power supply voltage, and a second power supply line formed on the back surface side of the first transistor; extending in the first direction; and supplying a second power supply voltage different from the first power supply voltage, a surface of each of the first nanosheet and the second nanosheet that is located on a first side which is one side in the second direction is exposed from the first gate line, the first power supply line is disposed at an end portion of the first standard cell that is located on the first side, and the second power supply line is disposed at an end portion of the first standard cell that is located on a second side which is the other side in the second direction.

According to the present disclosure, in plan view, the first power supply line is disposed on part of the first standard cell that is located on the first side which is one side in the second direction. In plan view, the second power supply line is disposed on part of the first standard cell that is located on the second side which is the other side in the second direction. Accordingly, by the first standard cell being disposed in the circuit block, the first standard cell can be shared with the standard cell disposed on part of the first standard cell that is located on the first side and the first power supply line, and also can be shared with the standard cell disposed on part of the first standard cell that is located on the second side and the second power supply line. Thus, the power supply lines for supplying the power supply voltages can be reinforced. Therefore, it is possible to reduce a decrease in the power supply voltage, and also it is possible to reduce occurrence of electromigration due to current concentration.

Regarding a standard cell using a CFET, the present disclosure provides the layout of a semiconductor integrated circuit device including a standard cell using a forksheet transistor as a transistor, where it is possible to reduce a decrease in the power supply voltage, and also it is possible to reduce occurrence of electromigration due to current concentration.

### BRIEF DESCRIPTION OF THE DRAWINGS

FIG. 1 is a plan view showing a layout example of a circuit block provided in a semiconductor integrated circuit device according to an embodiment.

FIG. 2 is a plan view showing an example of the layout structure of an inverter cell according to the embodiment.

FIG. 3 is a sectional view of the inverter cell of FIG. 2.

FIG. 4 is a circuit diagram of the inverter cell of FIG. 2.

FIG. 5 is another configuration example of the semiconductor integrated circuit device according to the embodiment.

FIG. 6 is a plan view showing an example of the layout structure of the inverter cell according to a variation of the embodiment.

FIG. 7 is a plan view showing an example of the layout structure of a 2-input NAND cell according to the embodiment.

FIG. 8 is a plan view showing an example of the layout structure of a 2-input NOR cell according to the embodiment.

FIG. 9 is a circuit diagram of the standard cells of FIGS. 7 and 8

### DETAILED DESCRIPTION

Embodiments will be described below with reference to the drawings. In the following embodiments, a semiconductor integrated circuit device includes a plurality of standard cells. It is assumed that at least some of the plurality of standard cells include a forksheet transistor having a gate electrode in a fork shape among nanosheet FETs and further have a CFET structure in which transistors of different conductivity types (in the embodiments, a cell lower portion is of a P conductivity type, and a cell upper portion is of an N conductivity type) are stacked on each other.

In this specification, “VDD” and “VSS” indicate a power supply voltage or a power source itself. In this specification, expressions indicating that the widths and the like are the same, such as “the same line width”, shall be understood to include manufacturing tolerances.

### Configuration of Circuit Block

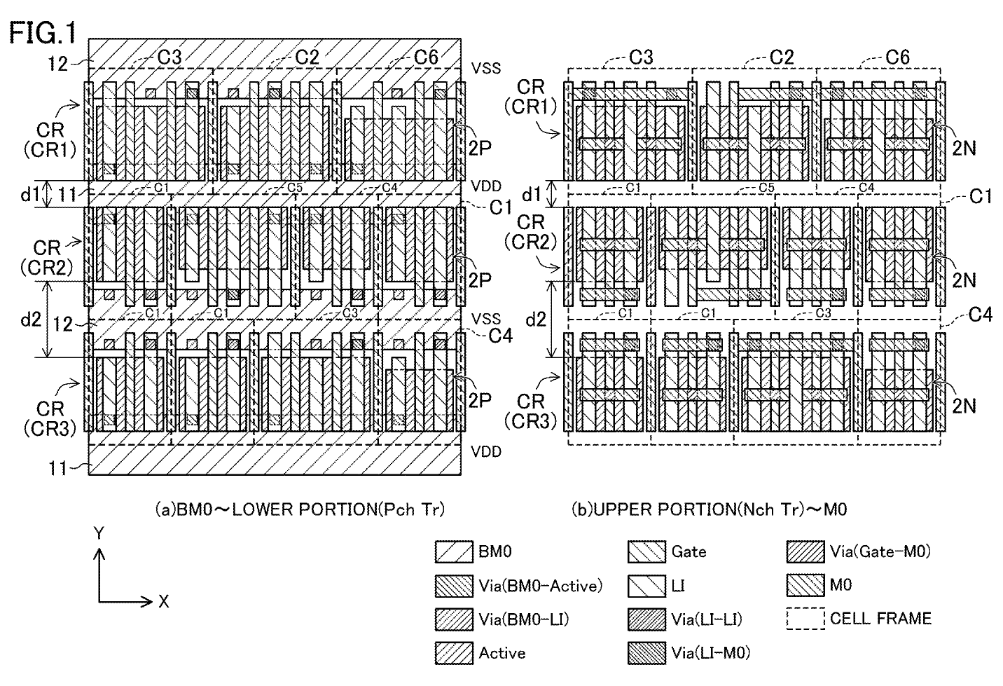

FIG. 1 is a plan view showing an example of the layout of a circuit block in the semiconductor integrated circuit device according to an embodiment. Specifically, FIG. 1(a) shows a portion including a forksheet transistor formed in a cell lower portion, that is, on the side close to a substrate, and FIG. 1(b) shows a portion including a forksheet transistor formed in a cell upper portion, that is, on the side distant from the substrate.

The block layout of FIG. 1 is formed by disposing the standard cells. In this embodiment, a power supply line is formed in a backside metal 0 (BM0) wiring layer, which is a back wiring layer provided on the back surface of a semiconductor chip on which a transistor is formed.

In the following description, in the plan view of FIG. 1 and others, the lateral direction of the drawing is the X direction (or the first direction), the longitudinal direction of the drawing is the Y direction (or the second direction), and the direction perpendicular to a substrate surface is the Z direction (or the depth direction). Further, in the following description, the same reference characters represent the same elements, and the descriptions thereof may be omitted.

In the plan view of FIG. 1 and others, a dotted line that surrounds the cell indicates a cell frame of the standard cell (an outer edge of the standard cell). The standard cell is disposed so that its cell frame is in contact with a cell frame of an adjacent cell in the X direction or the Y direction.

In the layout of FIG. 1, a plurality of cells arranged in the X direction form cell rows CR (CR1 to CR3). The plurality of cell rows CR (three rows in FIG. 1) are disposed in the Y direction. The plurality of cells include cells having logic functions, such as an inverter, a NAND gate, and a NOR gate. For example, the plurality of cells include inverter cells C1, C4; 2-input NAND cells C2, C5; 2-input NOR cells C3, C6; and the like, each described later.

In each cell, power supply lines are formed at both ends of the BM0 wiring layer in the Y direction, and each cell is supplied with the power supply voltages VDD, VSS from the outside through these power supply lines. The cell rows CR are disposed so that they are alternately inverted in the Y direction. At a boundary between the cell rows CR adjacent to each other, the power supply line (the power supply line 11 described later) that supplies the power supply voltage VDD is continuous in the X direction, and the power supply line (the power supply line 12 described later) that supplies the power supply voltage VSS is continuous in the X direction. That is, in the BM0 wiring layer, the power supply lines extending in the X direction are formed, and the power supply lines that supply the power supply voltage VDD and the power supply lines that supply the power supply voltage VSS are alternately disposed in the Y direction.

At a cell boundary, the cell rows CR1, CR2 adjacent to each other in the Y direction share the power supply line 11 which is continuous in the X direction and which supplies the power supply voltage VDD. At a cell boundary, the cell rows CR2, CR3 adjacent to each other in the Y direction share the power supply line 12 which is continuous in the X direction and which supplies the power supply voltage VSS. That is, in the block layout of FIG. 1, the cell rows CR adjacent to each other in the Y direction share the power supply line formed at the cell boundary. Since the cell rows CR adjacent to each other in the Y direction share the power supply line, the power supply line is reinforced. Therefore, it is possible to reduce a decrease in the power supply voltage, and also it is possible to reduce occurrence of electromigration due to current concentration.

An active region 2P that forms the channel, source, and drain of a P-type transistor is formed in the lower portion of each cell. An active region 2N that forms the channel, source, and drain of an N-type transistor is formed in the upper portion of each cell. In the cell row CR, the active regions 2P are aligned in the X direction, and the active regions 2N are aligned in the X direction.

Although the details will be described later, in the standard cell disposed in the cell row CR1, the active region 2P (2N) contains a nanosheet of which the surface located on the upper side in the Y direction in the drawing is not exposed from a gate line, and the surface located on the lower side in the Y direction in the drawing is exposed from a gate line. In the standard cell disposed in the cell row CR2, the active region 2P (2N) contains a nanosheet of which the surface located on the upper side in the Y direction in the drawing is exposed from a gate line, and the surface located on the lower side in the Y direction in the drawing is not exposed from a gate line. In the standard cell disposed in the cell row CR3, the active region 2P (2N) contains a nanosheet of which the surface located on the upper side in the Y direction in the drawing is not exposed from a gate line, and the surface located on the lower side in the Y direction in the drawing is exposed from a gate line. That is, in the block layout of FIG. 1, the cells adjacent to each other in the Y direction are disposed so that the nanosheets in the active regions face each other in the Y direction while the surfaces exposed from the gate line face each other in the Y direction and the surfaces not exposed from the gate line face each other in the Y direction. Specifically, the nanosheet in the active region 2P (2N) of the standard cell disposed in the cell row CR1 and the nanosheet in the active region 2P (2N) of the standard cell disposed in the cell row CR2 are disposed so that the surfaces facing each other in the Y direction are exposed from the gate line. The nanosheet in the active region 2P (2N) of the standard cell disposed in the cell row CR2 and the nanosheet in the active region 2P (2N) of the standard cell disposed in the cell row CR3 are disposed so that the surfaces facing each other in the Y direction are not exposed from the gate line. Accordingly, it is possible to shorten the distance d1 between the active region 2P (2N) of the standard cell disposed in the cell row CR1 and the active region 2P (2N) of the standard cell disposed in the cell row CR2, and therefore it is possible to reduce the area of the semiconductor integrated circuit device. In other words, the distance d1 between the active region 2P (2N) of the standard cell disposed in the cell row CR1 and the active region 2P (2N) of the standard cell disposed in the cell row CR2 is smaller than the distance d2 between the active region 2P (2N) of the standard cell disposed in the cell row CR2 and the active region 2P (2N) of the standard cell disposed in the cell row CR3.

The standard cells disposed in the cell row CR1 are disposed so that in the active region 2P (2N), the lower ends located on the lower side in the drawing are disposed at the same position in the Y direction. The standard cells disposed in the cell row CR2 are disposed so that in the active region 2P (2N), the upper ends located on the upper side in the drawing are disposed at the same position in the Y direction. The standard cells disposed in the cell row CR3 are disposed so that in the active region 2P (2N), the lower ends located on the lower side in the drawing are disposed at the same position in the Y direction. That is, in the cell row CR1, the lower ends of the active regions 2P (2N) that are located on the lower side in the Y direction in the drawing are aligned. In the cell row CR2, the upper ends of the active regions 2P (2N) that are located on the upper side in the Y direction in the drawing are aligned. In the cell row CR3, the lower ends of the active regions 2P (2N) that are located on the lower side in the Y direction in the drawing are aligned. In the standard cell disposed in the cell row CR1, the active region 2P (2N) contains the nanosheet of which the surface located on the lower side in the Y direction in the drawing is exposed from the gate line. In the standard cell disposed in the cell row CR2, the active region 2P (2N) contains the nanosheet of which the surface located on the upper side in the Y direction in the drawing is exposed from the gate line. In the standard cell disposed in the cell row CR3, the active region 2P (2N) contains the nanosheet of which the surface located on the lower side in the Y direction in the drawing is exposed from the gate line. That is, the standard cells disposed in the cell row CR1 are disposed so that the positions of the surfaces of the nanosheets that are exposed from the gate line are aligned in the Y direction. The standard cells disposed in the cell row CR2 are disposed so that the positions of the surfaces of the nanosheets that are exposed from the gate line are aligned in the Y direction. The standard cells disposed in the cell row CR3 are disposed so that the positions of the surfaces of the nanosheets that are exposed from the gate line are aligned in the Y direction. Here, in the forksheet FET, the nanosheets exposed from the gate line and facing each other are formed while a structure comprised of an insulator is provided therebetween. Thus, as in the configuration of FIG. 1, in the cell row in which the standard cells are arranged in the X direction, the positions of the surfaces of the nanosheets that are exposed from the gate line are aligned in the Y direction, so that the shape of the structure, or in other words, the size and installation range of the structure in the Y direction can be made constant. Accordingly, it is possible to facilitate manufacture of the semiconductor integrated circuit device.

### Configuration of Inverter Cell C1

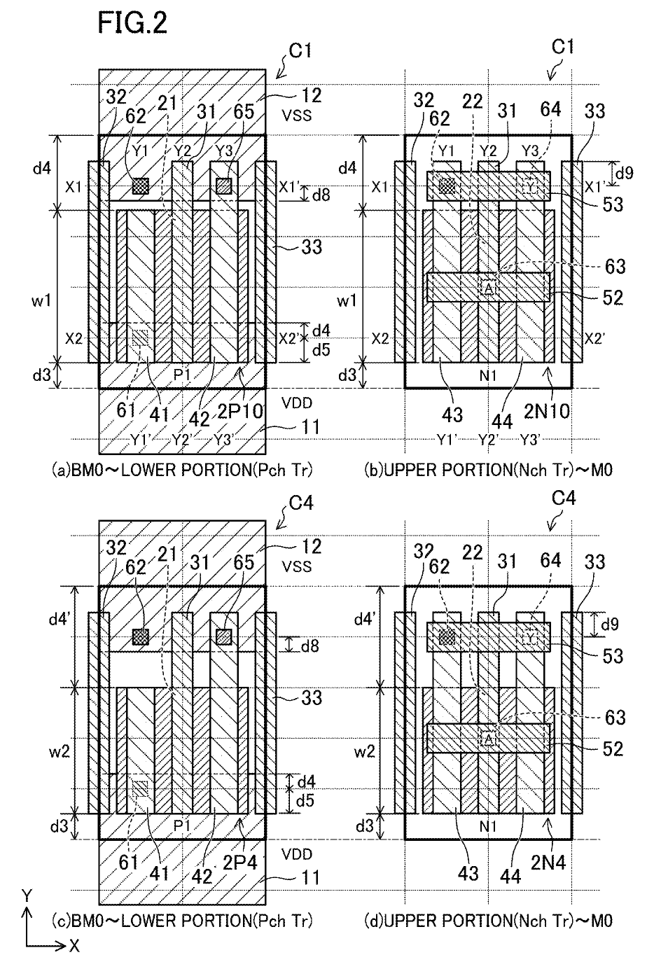

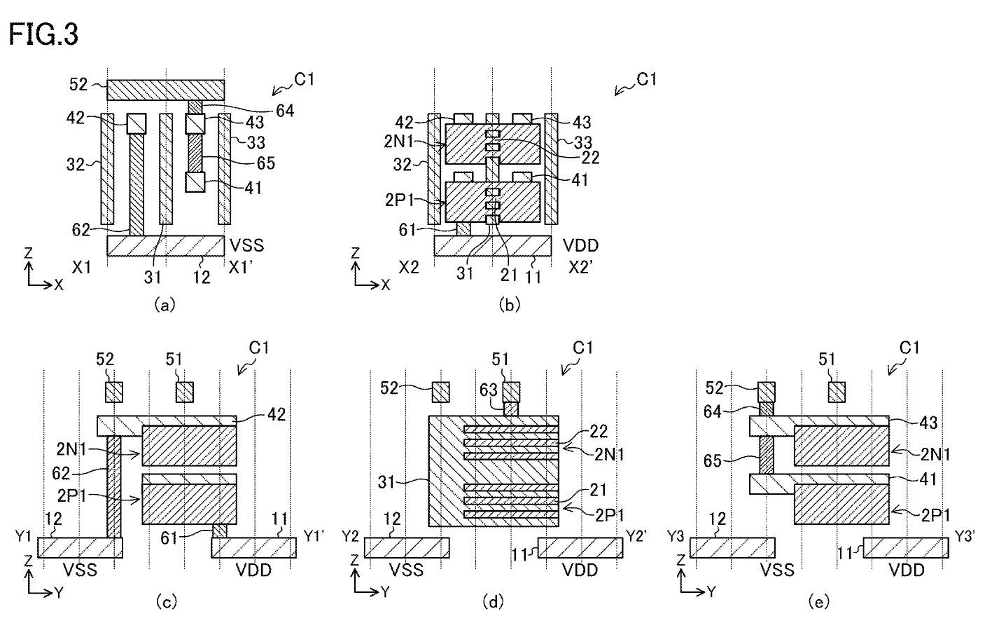

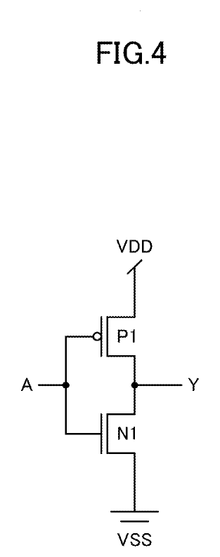

FIG. 2 is a plan view showing an example of layout structures of the inverter cells C1, C4 of the embodiment; FIG. 3 is a sectional view showing an example of a layout structure of an inverter cell of the embodiment; and FIG. 4 is a circuit diagram of the inverter cell of the embodiment. Specifically, FIG. 2(a) shows a cell lower portion of the inverter cell C1; FIG. 2(b) shows a cell upper portion of the inverter cell C1; FIG. 2(c) shows a cell lower portion of the inverter cell C4; FIG. 2(d) shows a cell upper portion of the inverter cell C4; FIG. 3(a) shows a cross section taken along line X1-X1′ of FIGS. 2(a) and 2(b); FIG. 3(b) shows a cross section taken along line Y1-Y1’ of FIGS. 2(a) and 2(b); FIG. 3(c) shows a cross section taken along line Y2-Y2’ of FIGS. 2(a) and 2(b); and FIG. 3(d) shows a cross section taken along line Y3-Y3’ of FIGS. 2(a) and 2(b).

In the following description, the dashed lines running longitudinally and laterally in the plan views of FIG. 2 and others and the dashed lines running longitudinally in the sectional views of FIG. 2 and others indicate grids used for locating components at the time of designing. The grids are disposed at equal intervals in the X direction, and are disposed at equal intervals in the Y direction. The grid intervals in the X direction may be the same as or may be different from those in the Y direction. The grid intervals may be different in different layers. Further, each component is not necessarily disposed on the grid.

As shown in FIG. 4, the inverter cell C1 has transistors P1, N1, and forms an inverter circuit with an input A and an output Y.

As shown in FIG. 2(a), the BM0 wiring layer, which is a wiring layer, is formed on the back surface of the semiconductor chip on which the transistors are formed. In the BM0 wiring layer, power supply lines 11, 12 extending in the X direction are formed. The power supply line 11 is formed at a lower end portion of the cell in the Y direction in the drawing, and supplies the power supply voltage VDD. The power supply line 12 is formed at an upper end portion of the cell in the Y direction in the drawing, and supplies the power supply voltage VSS.

The active region forming the channel, source, and drain of the P-type transistor is formed in the P-type transistor region in the cell lower portion. Specifically, an active region 2P1 is formed in the P-type transistor region. The active region 2P1 overlaps with the power supply line 11 in plan view.

A P-type transistor P1 is formed in the P-type transistor region. The transistor P1 has a nanosheet 21 as a channel which has a sheet structure with three sheets overlapping with each other in plan view and which extends in the X direction. Part of the active region 2P1 that serves as the source of the transistor P1 is connected with the power supply line 11 through a via 61. The via 61 is formed in a region in which the power supply line 11 and the active region 2P1 overlap with each other in plan view.

As shown in FIG. 2(b), the active region forming the channel, source, and drain of the N-type transistor is formed in the N-type transistor region in the cell upper portion. Specifically, an active region 2N1 is formed in the N-type transistor region. The active region 2N1 is disposed above the active region 2P1 in the Z direction. The active region 2N1 overlaps with the active region 2P1 in plan view.

An N-type transistor N1 is formed in the N-type transistor region. The transistor N1 has a nanosheet 22 as a channel which has a sheet structure with three sheets overlapping with each other in plan view and which extends in the X direction.

In the active region, portions that serve as the source and the drain on both sides of the nanosheet are formed by epitaxial growth of the nanosheet, for example.

At the center portion of the cell in the X direction in the drawing, a gate line 31 extending in the Y direction and extending in the Z direction from the cell upper portion to the cell lower portion is formed. The nanosheets 21, 22 overlap with the gate line 31 in plan view. The gate line 31 corresponds to the gates of the transistors P1, N1.

As shown in FIG. 3(d), the gate line 31 covers the outer peripheries of the nanosheets 21, 22 in the Y direction and the Z direction so that part of the outer peripheries of the nanosheets 21, 22 is exposed. Specifically, the side surfaces of the nanosheets 21, 22 that are located on the right side in the drawing are not covered with the gate line 31. That is, the side surfaces of the nanosheets 21, 22 that are located on the right side in the drawing are exposed from the gate line 31. Therefore, in FIG. 2, the surface of each of the nanosheets 21, 22 that is located on the lower side in the Y direction in the drawing is exposed from the gate line 31, and the surface of each of the nanosheets 21, 22 that is located on the upper side in the Y direction in the drawing is covered with the gate line 31.

As shown in FIG. 2, dummy gate lines 32, 33 extending in the Y direction and the Z direction are formed on the cell frames on both sides in the X direction. The dummy gate line 32 is shared with other cells disposed on the left side in the drawing. The dummy gate line 33 is shared with other cells disposed on the right side in the drawing.

As shown in FIG. 2(a), a local line (LI: local interconnect) 41 extending in the Y direction is formed in the cell lower portion. The local line 41 is connected to part of the active region 2P1 that serves as the drain of the transistor P1.

As shown in FIG. 2(b), local lines 42, 43 extending in the Y direction are formed in the cell upper portion. The local line 42 is connected with part of the active region 2N1 that serves as the source of the transistor N1. The local line 42 is connected with the power supply line 12 through a via 62. The via 62 is formed in a region in which the power supply line 12 and the local line 42 overlap with each other in plan view. That is, through the via 62 and the local line 42, the power supply line 12 is connected with part of the active region 2N1 that serves as the source of the transistor N1. The local line 43 is connected to part of the active region 2N1 that serves as the drain of the transistor N1.

In the M0 wiring layer, which is a metal wiring layer disposed above the active region 2N1, the lines 51, 52 extending in the X direction are formed. The line 51 corresponds to the input A, and the line 52 corresponds to the output Y.

The line 51 is disposed near a center portion of the cell in the Y direction. The line 51 is connected with the gate line 31 through a via 63. The via 63 is formed in a region in which the line 51 and the active region 2N1 overlap with each other in plan view.

The line 52 is disposed on the upper side in the Y direction in the drawing. Through vias 64, 65 and the local lines 41, 42, the line 52 is connected with a portion that serves as the drain of the transistor P1 and a portion that serves as the drain of the transistor N1.

As described above, the inverter cell C1 has the P-type transistor P1 and the N-type transistor N1, and forms the inverter circuit with the input A and the output Y.

As shown in FIGS. 2(a) and 2(b), the active region 2P1, 2N1 in the inverter cell C1 has a width w1 in the Y direction in plan view.

In the inverter cell C1 shown in FIG. 2, the surfaces of the nanosheets 21, 22 that are located on the lower side in the Y direction in the drawing are exposed from the gate line 31. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d3 from the lower end of the active region 2P1 (2N1) in the Y direction in the drawing to the lower end of the cell frame in the Y direction in the drawing. In other words, the active regions 2P1, 2N1 (the nanosheets 21, 22) can be disposed close to the lower end of the cell frame in the Y direction in the drawing. Therefore, the area of the semiconductor integrated circuit device can be reduced.

The surfaces of the nanosheets 21, 22 that are located on the upper side in the Y direction in the drawing are not exposed from the gate line 31. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d3 from the lower end of the active region 2P1 (2N1) in the Y direction in the drawing to the lower end of the cell frame in the Y direction in the drawing is smaller than the distance d4 from the upper end of the active region 2P1 (2N1) in the Y direction in the drawing to the upper end of the cell frame in the Y direction in the drawing. In other words, in plan view, the active region 2P1 (2N1) is disposed close to the lower end of the cell frame in the drawing with respect to the center of the cell frame in the Y direction in the drawing. That is, in plan view, the center portion of the active region 2P1 (2N1) in the Y direction in the drawing is located on the lower side in the drawing with respect to the center portion of the cell frame in the Y direction in the drawing.

In plan view, the power supply line 11 is formed at the lower end portion of the cell in the Y direction in the drawing, and are shared with the standard cell disposed on the lower side of the inverter cell C1 in the Y direction in the drawing. In plan view, the power supply line 12 is formed at the upper end portion of the cell in the Y direction in the drawing, and are shared with the standard cell disposed on the upper side of the inverter cell C1 in the Y direction in the drawing. Accordingly, by the inverter cell C1 being disposed in the circuit block of FIG. 1, the power supply lines for supplying the power supply voltages VDD, VSS can be reinforced. Therefore, it is possible to reduce a decrease in the power supply voltage, and also it is possible to reduce occurrence of electromigration due to current concentration.

The via 61 that connects the power supply line 11 and part of the active region 2P1 that serves as the source of the transistor P1 is formed in a region in which the power supply line 11 and the active region 2P1 overlap with each other in plan view. In plan view, the via 61 is disposed close to the upper side in the drawing in the region in which the power supply line 11 and the active region 2P1 overlap with each other in plan view. In other words, in plan view, the distance d5 in the Y direction from the center portion of the via 61 in the drawing to the upper end of the power supply line 11 in the drawing is smaller than the distance d6 in the Y direction from the center portion of the via 61 in the drawing to the lower end of the active region 2P1 in the drawing. Accordingly, the via 61 is disposed close to the center portion of the active region 2P1 in the Y direction in the drawing, and therefore the difference is reduced between the resistance value from the via 61 to the upper end of the nanosheet 21 of the transistor P1 in the active region 2P1 in the drawing and the resistance value from the via 61 to the lower end of the nanosheet 21 of the transistor P1 in the active region 2P1 in the drawing. Therefore, the current flowing through the transistor P1 is equalized in the Y direction, or in the up-down direction in the drawing, and thus it is possible to increase the speed of the semiconductor integrated circuit device.

Through the via 62 and the local line 42, the power supply line 12 is connected with part of the active region 2N1 that serves as the source of the transistor N1. The length of the via 62 is longer in the Z direction because the via 62 connects the power supply line 12 formed in the BM0 wiring layer and the local line 42 formed in the cell upper portion. As described above, the distance d3 from the lower end of the active region 2P1 (2N1) in the Y direction in the drawing to the lower end of the cell frame in the Y direction in the drawing is smaller than the distance d4 from the upper end of the active region 2P1 (2N1) in the Y direction in the drawing to the upper end of the cell frame in the Y direction in the drawing. Accordingly, it is possible to expand the area from the upper end of the active region 2P1 (2N1) in the Y direction in the drawing to the upper end of the cell frame in the Y direction in the drawing, and therefore the via 62 can be easily formed in that region. Therefore, the semiconductor integrated circuit device can be easily manufactured, and the yield and reliability can be improved.

The via 62 is formed in a region in which the power supply line 12 and the local line 42 overlap with each other in plan view. In plan view, the via 62 is disposed close to the lower side in the drawing in the region in which the power supply line 12 and the local line 42 overlap with each other in plan view. In other words, in plan view, the distance d7 in the Y direction from a center portion of the via 62 in the drawing to the lower end of the power supply line 12 in the drawing is smaller than the distance d8 in the Y direction from the center portion of the via 62 in the drawing to the upper end of the local line 42 in the drawing. Accordingly, the via 62 is disposed even closer to the active region 2N1. Therefore, it is possible to reduce a resistance value from the power supply line 12 to part of the active region 2N1 that serves as the source of the transistor N1, and thus it is possible to increase the speed of the semiconductor integrated circuit device.

The via 63 that connects the line 51 and the gate line 31 is formed in a region to overlap with the active region 2N1 and the gate line 31 in plan view. Accordingly, it is possible to shorten the distance from the line 51 (the input A) to part of the gate line 31 overlapping with the nanosheets 21, 22 in plan view that covers the nanosheets 21, 22. Therefore, it is possible to reduce a resistance value from the line 51, and thus it is possible to increase the speed of the semiconductor integrated circuit device.

The line 52 is disposed on the upper side in the Y direction in the drawing with respect to the line 51 (the side on which the nanosheet 22 is not exposed from the gate line 31 and which is opposite to the side on which the active region 2N1 is disposed close to the cell frame). The via 64 that connects the line 52 and the local line 43 and the via 65 that connects the local lines 43, 41 are formed on the upper side in the Y direction in the drawing in plan view with respect to the line 51. Accordingly, it is possible to shorten the distance from the line 52 to part of the active region 2P1 that serves as the drain of the transistor P1 and the distance from the line 52 to part of the active region 2N1 that serves as the drain of the transistor N1. Therefore, it is possible to reduce a resistance value from the line 52 to part of the active region 2P1 (2N1) that serves as the drain of the transistor P1 (N1), and thus it is possible to increase the speed of the semiconductor integrated circuit device.

### Configuration of Inverter Cell C4

The inverter cell C4 and the inverter cell C1 have substantially the same configuration. Specifically, the inverter cell C4 has the P-type transistor P1 and the N-type transistor N1, and forms the inverter circuit with the input A and the output Y.

As shown in FIGS. 2(c) and 2(d), the inverter cell C4 has an active region 2P4, 2N4 which is different in width in the Y direction from the active region 2P1, 2N1 in the inverter cell C1 shown in FIGS. 2(a) and 2(b).

Specifically, the width of the active region 2P4, 2N4 in the Y direction is w2. The width w2 is smaller than the width w1. That is, the drive capability of the inverter cell C1 is greater than the drive capability of the inverter cell C4.

As shown in FIG. 2, the lower end of the active region 2P4 (2N4) in the Y direction in the drawing is disposed at the same position in the Y direction as the lower end of the active region 2P1 (2N1) in the Y direction in the drawing. That is, the lower end of the active region 2P1 (2N1) of the inverter cell C1 in the Y direction in the drawing and the lower end of the active region 2P4 (2N4) of the inverter cell C4 in the Y direction in the drawing are aligned in the Y direction. In the inverter cells C1, C4, the surface of the nanosheet 21 (22) that is located on the lower side in the Y direction in the drawing is exposed from the gate line 31. That is, in the inverter cells C1, C4, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two inverter cells of which the active regions are different in width are disposed in the circuit block, but three or more inverter cells of which the active regions are different in width may be disposed in the circuit block. In this case, in each inverter cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Other Configuration Examples

The above-described power supply line formed on the back surface side of the transistor may be configured using a semiconductor chip different from the semiconductor chip in which the transistor is formed.

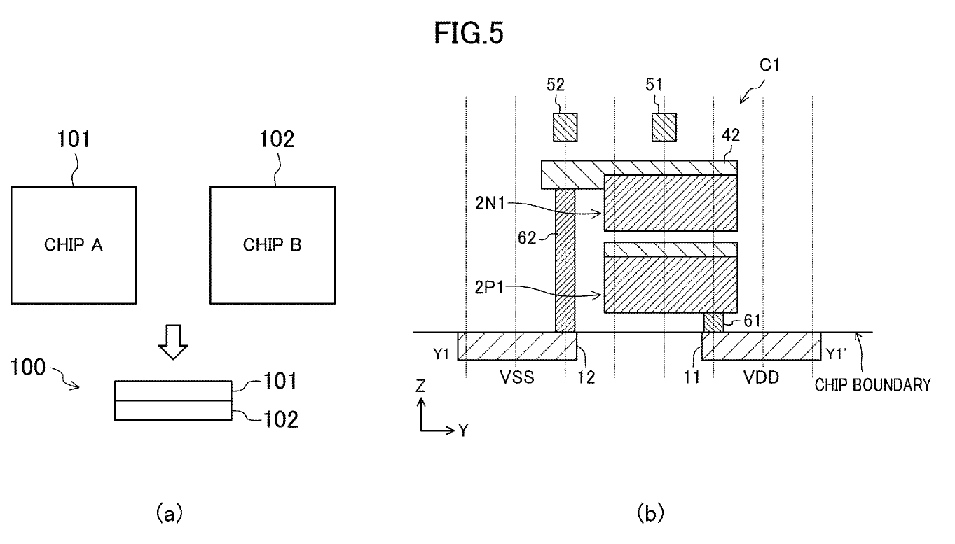

FIG. 5(a) is another configuration example of the semiconductor integrated circuit device of the embodiment. A semiconductor integrated circuit device 100 shown in FIG. 5(a) is formed of a first semiconductor chip 101 (chip A) and a second semiconductor chip 102 (chip B) stacked on each other. The above-described standard cell and the like including an inverter cell are disposed on the chip A. A power supply line is formed in a wiring layer provided on the surface of the chip B. The chip B is bonded to the back surface side of the chip A using a bump or the like.

FIG. 5(b) shows a cross section of the inverter cell C1 of FIG. 2 taken along line Y1-Y1’ according to this configuration example. As shown in FIG. 5(b), the wiring layer on the surface of the chip B is formed with the power supply line 11 that supplies the power supply voltage VDD and the power supply line 12 that supplies the power supply voltage VSS. The power supply line 11 is connected with the active region 2P1 of the chip A through the via 61. The power supply line 12 is connected with the active region 2N1 of the chip A through the via 62 and the local line 42.

This configuration example can also provide the same advantages as those of the inverter cell described above.

### Variations

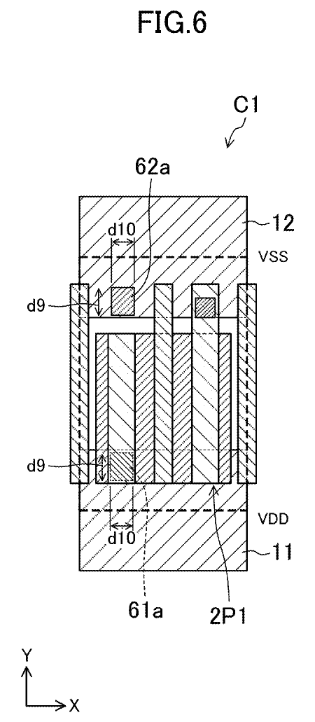

FIG. 6 is a plan view showing an example of the layout structure of the inverter cell according to a variation of the embodiment. FIG. 6 shows the cell lower portion. In FIG. 6, as compared with FIG. 2(a), vias 61a, 61a are disposed instead of the vias 61, 62.

As shown in FIG. 6, the cross section of the vias 61a, 62a is rectangular in plan view. Specifically, the length d9 of each of the vias 61a, 62b in the Y direction is longer than the length d10 in the X direction.

In plan view, the length d9 of the via 61a in the Y direction is substantially the same as the length from the upper end of the power supply line 11 in Y direction in the drawing to the lower end of the active region 2P1 in the drawing. In plan view, the length d9 of the via 62a in the Y direction is substantially the same as the length from the upper end of the local line 42 in Y direction in the drawing to the lower end of the power supply line 12 in the Y direction in the drawing.

According to the configuration of FIG. 6, the resistance value of the via 61a that connects the power supply line 11 and part of the active region 2P1 that serves as the source of the transistor P1, and the resistance value of the via 62a that connects the power supply line 12 and part of the active region 2N1 that serves as the source of the transistor N1 can be reduced. Therefore, it is possible to reduce a decrease in the power supply voltage, and also it is possible to reduce occurrence of electromigration.

The length of the via 62a is longer in the Z direction because the via 62a connects the power supply line 12 formed in the BM0 wiring layer and the local line 42 formed in the cell upper portion. Thus, by reducing the resistance value of the via 62a, it is possible to reduce the power supply voltage more effectively.

In FIG. 6, the vias 61a, 62a are disposed instead of the vias 61, 62 of FIG. 2, but the configuration is not limited to this. Either one of the vias 61, 62 of FIG. 2 may be replaced with the via 61a, 62a. In this case, by replacing the via 62 of FIG. 2 with the via 62a, it is possible to reduce the power supply voltage more effectively.

### Other Layout Structures of Standard Cell

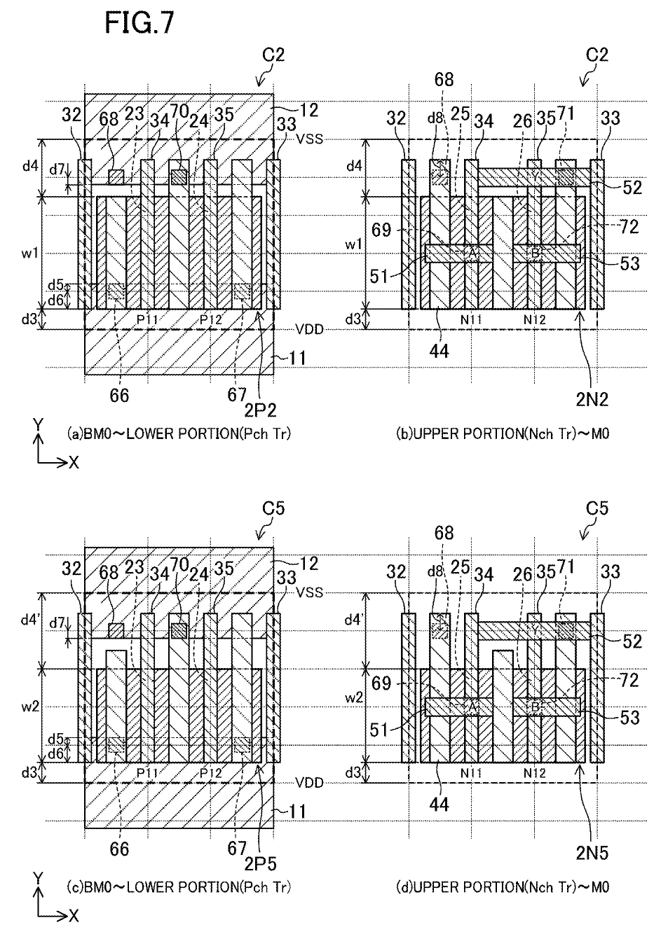

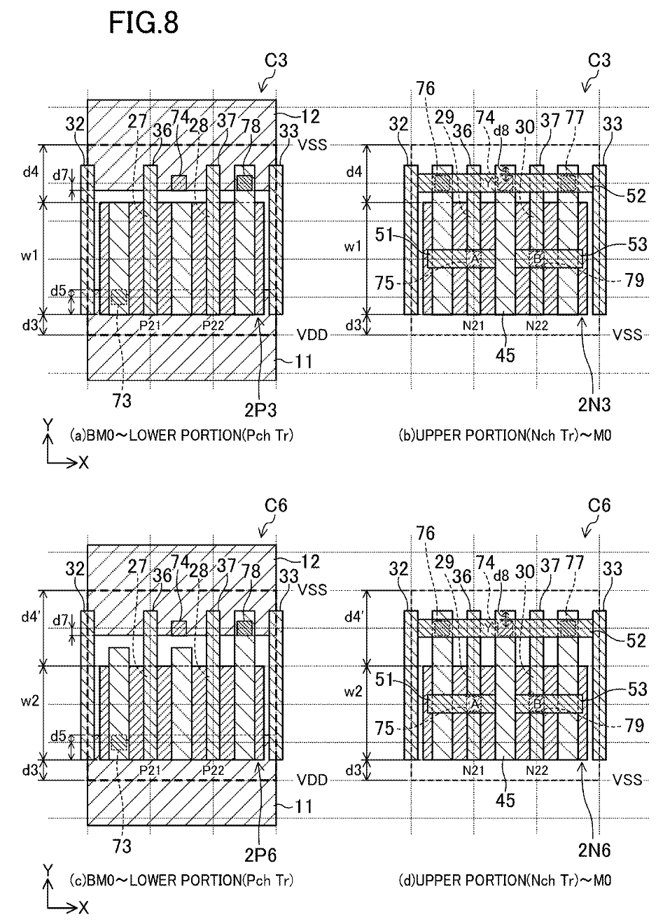

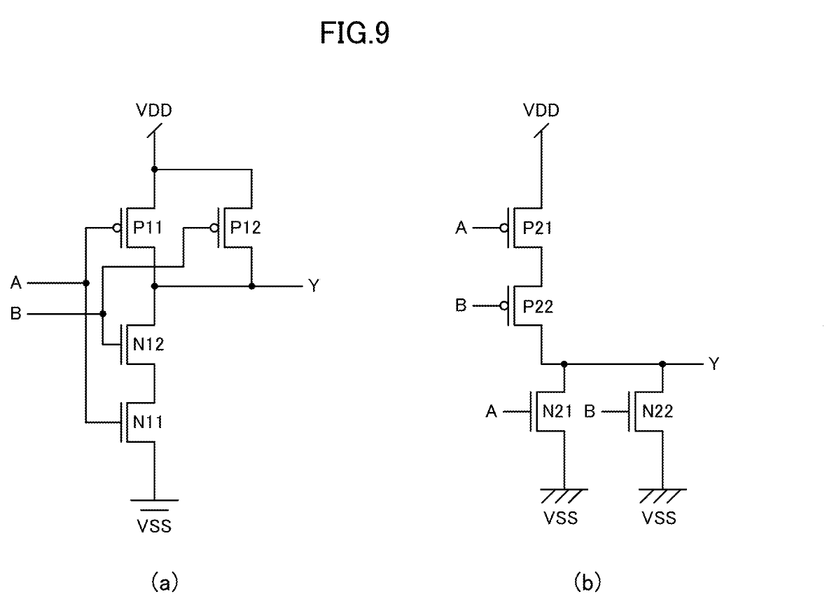

FIGS. 7 and 8 are plan views showing examples of the layout structure of the cell contained in the semiconductor integrated circuit device of the embodiment. FIG. 7(a) is a cell lower portion of the 2-input NAND cell C2. FIG. 7(b) is a cell upper portion of the 2-input NAND cell C2. FIG. 7(c) is a cell lower portion of the 2-input NAND cell C5. FIG. 7(d) is a cell upper portion of the 2-input NAND cell C5. FIG. 8(a) is a cell lower portion of the 2-input NOR cell C3. FIG. 8(b) is a cell upper portion of the 2-input NOR cell C3. FIG. 8(c) is a cell lower portion of the 2-input NOR cell C6. FIG. 8(d) is a cell upper portion of the 2-input NOR cell C6. FIG. 9(a) is a circuit diagram of the 2-input NAND cell. FIG. 9(b) is a circuit diagram of the 2-input NOR cell.

The layout structures of FIGS. 7 and 8 can be easily understood from the above description of the inverter cell and the circuit diagrams of FIG. 9, and therefore, the description thereof will be omitted.

### Configuration of 2-Input NAND Cell C2

As shown in FIG. 7(a), in the BM0 wiring layer, power supply lines 11, 12 extending in the X direction are formed. The power supply line 11 is formed at a lower end portion of the cell in the Y direction in the drawing, and supplies the power supply voltage VDD. The power supply line 12 is formed at an upper end portion of the cell in the Y direction in the drawing, and supplies the power supply voltage VSS.

An active region 2P2 is formed in a P-type transistor region in the cell lower portion. In the active region 2P2, transistors P11, P12 are formed. The transistors P11, P12 have nanosheets 23, 24 extending in the X direction, respectively. Part of the active region 2P2 that serves as the source of the transistor P11, P12 is connected with the power supply line 11 through a via 66, 67. The vias 66, 67 are formed in a region in which the power supply line 11 and the active region 2P2 overlap with each other in plan view.

As shown in FIG. 7(b), an active region 2N2 is formed in an N-type transistor region in the cell upper portion. The active region 2N2 overlaps with the active region 2P2 in plan view.

In the active region 2N2, transistors N11, N12 are formed. The transistors N11, N12 have nanosheets 25, 26 extending in the X direction, respectively.

Gate lines 34, 35 extending in the Y direction are formed. The nanosheets 23, 25 overlap with the gate line 34 in plan view. The nanosheets 24, 26 overlap with the gate line 35 in plan view. The gate line 34 corresponds to the gates of the transistors P11, N11. The gate line 35 corresponds to the gates of the transistors P12, N12.

The gate line 34 covers the outer peripheries of the nanosheets 23, 25 in the Y direction and the Z direction so that part of the outer peripheries of the nanosheets 23, 25 is exposed. The gate line 35 covers the outer peripheries of the nanosheets 24, 26 in the Y direction and the Z direction so that part of the outer peripheries of the nanosheets 24, 26 is exposed. Specifically, the surface of the nanosheets 23, 25 that is located on the lower side in the Y direction in the drawing is exposed from the gate line 34, and the surface of the nanosheets 23, 25 that is located on the upper side in the Y direction in the drawing is covered with the gate line 34. The surface of the nanosheets 24, 26 that is located on the lower side in the Y direction in the drawing is exposed from the gate line 35, and the surface of the nanosheets 24, 26 that is located on the upper side in the Y direction in the drawing is covered with the gate line 35.

As shown in FIG. 7(b), a local line 44 extending in the Y direction is formed in the cell upper portion. The local line 44 is connected with part of the active region 2N2 that serves as the source of the transistor N11 The local line 44 is connected with the power supply line 12 through a via 68. The via 68 is formed in a region in which the power supply line 12 and the local line 44 overlap with each other in plan view. That is, through the via 68 and the local line 44, the power supply line 12 is connected with part of the active region 2N2 that serves as the source of the transistor N11.

In the M0 wiring layer, lines 51 to 53 extending in the X direction are formed. The line 51 corresponds to the input A, the line 52 corresponds to the output Y, and the line 53 corresponds to the input B.

The line 51 is disposed near a center portion of the cell in the Y direction in the drawing. The line 51 is connected with the gate line 34 through a via 69. The via 69 is formed in a region in which the line 51 and the active region 2N2 overlap with each other in plan view.

The line 52 is disposed in an upper portion of the cell in the Y direction in the drawing. Through vias 70, 71 and the local line, the line 52 is connected with part of the active region 2P2 that serves as the drain of the transistors P11, P12 and part of the active region 2N2 that serves as the drain of the transistor N12.

The line 53 is disposed near a center portion of the cell in the Y direction in the drawing. The line 53 is connected with the gate line 35 through a via 72. The via 72 is formed in a region in which the line 53 and the active region 2N2 overlap with each other in plan view.

As described above, the 2-input NAND cell C2 has the P-type transistors P11, P12 and the N-type transistors N11, N12, and forms the NAND circuit with the inputs A, B and the output Y.

As shown in FIGS. 7(a) and 7(b), the active region 2P2, 2N2 in the 2-input NAND cell C2 has a width w1 in the Y direction in plan view.

In the 2-input NAND cell C2 shown in FIG. 7, the surfaces of the nanosheets 23, 25 that are located on the lower side in the Y direction in the drawing are exposed from the gate line 34. The surfaces of the nanosheets 24, 26 that are located on the lower side in the Y direction in the drawing are exposed from the gate line 35. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d3 from the lower end of the active region 2P2 (2N2) in the Y direction in the drawing to the lower end of the cell frame in the Y direction in the drawing. In other words, the active regions 2P2, 2N2 (the nanosheets 23 to 26) can be disposed close to the lower end of the cell frame in the Y direction in the drawing. Therefore, the area of the semiconductor integrated circuit device can be reduced.

The surfaces of the nanosheets 23, 25 that are located on the upper side in the Y direction in the drawing are not exposed from the gate line 34. The surfaces of the nanosheets 24, 26 that are located on the upper side in the Y direction in the drawing are not exposed from the gate line 35. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d3 from the lower end of the active region 2P2 (2N2) in the Y direction in the drawing to the lower end of the cell frame in the Y direction in the drawing is smaller than the distance d4 from the upper end of the active region 2P2 (2N2) in the Y direction in the drawing to the upper end of the cell frame in the Y direction in the drawing. In other words, in plan view, the active region 2P2 (2N2) is disposed close to the lower end of the cell frame in the drawing with respect to the center of the cell frame in the Y direction in the drawing. That is, in plan view, the center portion of the active region 2P2 (2N2) in the Y direction in the drawing is located on the lower side in the drawing with respect to the center portion of the cell frame in the Y direction in the drawing.

In plan view, the power supply line 11 is formed at the lower end portion of the cell in the Y direction in the drawing, and are shared with the standard cell disposed on the lower side of the 2-input NAND cell C2 in the Y direction in the drawing. In plan view, the power supply line 12 is formed at the upper end portion of the cell in the Y direction in the drawing, and are shared with the standard cell disposed on the upper side of the 2-input NAND cell C2 in the Y direction in the drawing. Accordingly, by the 2-input NAND cell C2 being disposed in the circuit block of FIG. 1, the power supply lines for supplying the power supply voltages VDD, VSS can be reinforced. Therefore, it is possible to reduce a decrease in the power supply voltage, and also it is possible to reduce occurrence of electromigration due to current concentration.

The via 66 (67) that connects the power supply line 11 and part of the active region 2P2 that serves as the source of the transistor P11 (P12) is formed in a region in which the power supply line 11 and the active region 2P2 overlap with each other in plan view. In plan view, the via 66 (67) is disposed close to the upper side in the drawing in the region in which the power supply line 11 and the active region 2P2 overlap with each other in plan view. In other words, in plan view, the distance d5 in the Y direction from the center portion of the via 66 (67) in the drawing to the upper end of the power supply line 11 in the drawing is smaller than the distance d6 in the Y direction from the center portion of the via 66 (67) in the drawing to the lower end of the active region 2P2 in the drawing. Accordingly, the via 66 (67) is disposed close to the center portion of the active region 2P2 in the Y direction in the drawing, and therefore the difference is reduced between the resistance value from the via 66 (67) to the upper end of the nanosheet 23, 24 of the transistor P11 (P12) in the active region 2P2 in the drawing and the resistance value from the via 66 (67) to the lower end of the nanosheet 23, 24 of the transistor P11 (P12) in the active region 2P2 in the drawing. Therefore, the current flowing through the transistor P11 (P12) is equalized in the Y direction, or in the up-down direction in the drawing, and thus it is possible to increase the speed of the semiconductor integrated circuit device.

Through the via 68 and the local line 44, the power supply line 12 is connected with part of the active region 2N2 that serves as the source of the transistor N11. The length of the via 68 is longer in the Z direction because the via 68 connects the power supply line 12 formed in the BM0 wiring layer and the local line 44 formed in the cell upper portion. As described above, the distance d3 from the lower end of the active region 2P2 (2N2) in the Y direction in the drawing to the lower end of the cell frame in the Y direction in the drawing is smaller than the distance d4 from the upper end of the active region 2P2 (2N2) in the Y direction in the drawing to the upper end of the cell frame in the Y direction in the drawing. Accordingly, it is possible to expand the area from the upper end of the active region 2P2 (2N2) in the Y direction in the drawing to the upper end of the cell frame in the Y direction in the drawing, and therefore the via 68 can be easily formed in that region. Therefore, the semiconductor integrated circuit device can be easily manufactured, and the yield and reliability can be improved.

The via 68 is formed in a region in which the power supply line 12 and the local line 44 overlap with each other in plan view. In plan view, the via 68 is disposed close to the lower side in the drawing in the region in which the power supply line 12 and the local line 44 overlap with each other in plan view. In other words, in plan view, the distance d7 in the Y direction from a center portion of the via 68 in the drawing to the lower end of the power supply line 12 in the drawing is smaller than the distance d8 in the Y direction from the center portion of the via 68 in the drawing to the upper end of the local line 44 in the drawing. Accordingly, the via 68 is disposed even closer to the active region 2N2. Therefore, it is possible to reduce a resistance value from the power supply line 12 to part of the active region 2N2 that serves as the source of the transistor N11, and thus it is possible to increase the speed of the semiconductor integrated circuit device.

The via 69 (72) that connects the line 51 (53) and the gate line 34 (35) is formed in a region to overlap with the active region 2N2 and the gate line 34 (35) in plan view. Accordingly, it is possible to shorten the distance from the line 51 (53) (the input A (the input B)) to part of the gate line 34 (35) overlapping with the nanosheets 23, 25 (24, 26) in plan view that covers the nanosheets 23, 25 (24, 26). Therefore, it is possible to reduce a resistance value from the line 51 (53), and thus it is possible to increase the speed of the semiconductor integrated circuit device.

The line 52 is disposed on the upper side in the Y direction in the drawing with respect to the lines 51, 53 (the side on which the nanosheets 25, 26 are not exposed from the gate lines 34, 35, respectively, and which is opposite to the side on which the active region 2N2 is disposed close to the cell frame). The via 70 connects the line 52 and the local line connected to part of the active region 2P2 that serves as the drain of the transistors P11, P12. The via 71 connects the line 52 and the local line connected to part of the active region 2N2 that serves as the drain of the transistor N12. In plan view, the vias 70, 71 are formed on the upper side in the Y direction in the drawing with respect to the lines 51, 53. Accordingly, it is possible to shorten the distance from the line 52 to part of the active region 2P2 that serves as the drain of the transistor P11, P12 and the distance from the line 52 to part of the active region 2N2 that serves as the drain of the transistor N12. Therefore, it is possible to reduce a resistance value from the line 52 to part of the active region 2P2 (2N2) that serves as the drain of the transistor P11, P12 (N12), and thus it is possible to increase the speed of the semiconductor integrated circuit device.

### Configuration of 2-Input NAND Cell C5

The 2-input NAND cell C5 and the 2-input NAND cell C2 have substantially the same configuration. Specifically, the 2-input NAND cell C5 has the P-type transistors P11, P12 and the N-type transistors N11, N12, and forms the NAND circuit with the inputs A, B and the output Y.

As shown in FIGS. 7(c) and 7(d), the 2-input NAND cell C5 has an active region 2P5, 2N5 which is different in width in the Y direction from the active region 2P2, 2N2 in the 2-input NAND cell C2 shown in FIGS. 7(a) and 7(b).

Specifically, the width of the active region 2P5, 2N5 in the Y direction is w2. The width w2 is smaller than the width w1. That is, the drive capability of the 2-input NAND cell C2 is greater than the drive capability of the 2-input NAND cell C5.

As shown in FIG. 7, the lower end of the active region 2P5 (2N5) in the Y direction in the drawing is disposed at the same position in the Y direction as the lower end of the active region 2P2 (2N2) in the Y direction in the drawing. That is, the lower end of the active region 2P2 (2N2) of the 2-input NAND cell C2 in the Y direction in the drawing and the lower end of the active region 2P5 (2N5) of the 2-input NAND cell C5 in the Y direction in the drawing are aligned in the Y direction. In the 2-input NAND cell C2, C5, the lower surface of the nanosheets 23 (25) in the Y direction in the drawing is exposed from the gate line 34. In the 2-input NAND cell C2, C5, the lower surface of the nanosheet 24 (26) in the Y direction in the drawing is exposed from the gate line 35. That is, in the 2-input NAND cells C2, C5, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two 2-input NAND cells of which the active regions are different in width are disposed in the circuit block, but three or more 2-input NAND cells of which the active regions are different in width may be disposed in the circuit block. In this case, in each 2-input NAND cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Configuration of 2-Input NOR Cell C3

As shown in FIG. 8(a), in the BM0 wiring layer, power supply lines 11, 12 extending in the X direction are formed. The power supply line 11 is formed at a lower end portion of the cell in the Y direction in the drawing, and supplies the power supply voltage VDD. The power supply line 12 is formed at an upper end portion of the cell in the Y direction in the drawing, and supplies the power supply voltage VSS.

An active region 2P3 is formed in a P-type transistor region in the cell lower portion of the 2-input NOR cell C3. In the active region 2P3, transistors P21, P22 are formed. The transistors P21, P22 have nanosheets 27, 28 extending in the X direction, respectively. Part of the active region 2P3 that serves as the source of the transistor P21, P22 is connected with the power supply line 11 through a via 73. The via 73 is formed in a region in which the power supply line 11 and the active region 2P3 overlap with each other in plan view.

As shown in FIG. 8(b), an active region 2N3 is formed in an N-type transistor region in the cell upper portion. The active region 2N3 overlaps with the active region 2P3 in plan view.

In the active region 2N3, transistors N21, N22 are formed. The transistors N21, N22 have nanosheets 29, 30 extending in the X direction, respectively.

Gate lines 36, 37 extending in the Y direction are formed. The nanosheets 27, 29 overlap with the gate line 36 in plan view. The nanosheets 28, 30 overlap with the gate line 37 in plan view. The gate line 36 corresponds to the gates of the transistors P21, N21. The gate line 37 corresponds to the gates of the transistors P22, N22.

The gate line 36 covers the outer peripheries of the nanosheets 27, 29 in the Y direction and the Z direction so that part of the outer peripheries of the nanosheets 27, 29 is exposed. The gate line 37 covers the outer peripheries of the nanosheets 28, 30 in the Y direction and the Z direction so that part of the outer peripheries of the nanosheets 28, 30 is exposed. Specifically, the surface of the nanosheets 27, 29 that is located on the lower side in the Y direction in the drawing is exposed from the gate line 36, and the surface of the nanosheets 27, 29 that is located on the upper side in the Y direction in the drawing is covered with the gate line 36. The surface of the nanosheets 27, 29 that is located on the lower side in the Y direction in the drawing is exposed from the gate line 37, and the surface of the nanosheets 27, 29 that is located on the upper side in the Y direction in the drawing is covered with the gate line 37.

As shown in FIG. 8(b), a local line 45 extending in the Y direction is formed in the cell upper portion. The local line 45 is connected with part of the active region 2N3 that serves as the source of the transistors N21, N22. The local line 45 is connected with the power supply line 12 through a via 74. The via 74 is formed in a region in which the power supply line 12 and the local line 45 overlap with each other in plan view. That is, through the via 74 and the local line 45, the power supply line 12 is connected with part of the active region 2N3 that serves as the source of the transistors N21, N22.

In the M0 wiring layer, lines 51 to 53 extending in the X direction are formed. The line 51 corresponds to the input A, the line 52 corresponds to the output Y, and the line 53 corresponds to the input B.

The line 51 is disposed near a center portion of the cell in the Y direction in the drawing. The line 51 is connected with the gate line 36 through a via 75. The via 75 is formed in a region in which the line 51 and the active region 2N3 overlap with each other in plan view.

The line 52 is disposed in an upper portion of the cell in the Y direction in the drawing. Through vias 76 to 78 and the local line, the line 52 is connected with part of the active region 2P3 that serves as the drain of the transistor P22 and part of the active region 2N3 that serves as the drain of the transistor N21, N22.

The line 53 is disposed near a center portion of the cell in the Y direction in the drawing. The line 53 is connected with the gate line 37 through a via 79. The via 79 is formed in a region in which the line 53 and the active region 2N3 overlap with each other in plan view.

As described above, the 2-input NOR cell C3 has the P-type transistors P21, P22 and the N-type transistors N21, N22, and forms the NOR circuit with the inputs A, B and the output Y.

As shown in FIGS. 8(a) and 8(b), the active regions 2P3, 2N3 in the 2-input NOR cell C3 has a width w1 in the Y direction in plan view.

In the 2-input NOR cell C3 shown in FIG. 8, the surfaces of the nanosheets 27, 29 that are located on the lower side in the Y direction in the drawing are exposed from the gate line 36. The surfaces of the nanosheets 28, 30 that are located on the lower side in the Y direction in the drawing are exposed from the gate line 37. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d3 from the lower end of the active region 2P3 (2N3) in the Y direction in the drawing to the lower end of the cell frame in the Y direction in the drawing. In other words, the active regions 2P3, 2N3 (the nanosheets 27 to 30) can be disposed close to the lower end of the cell frame in the Y direction in the drawing. Therefore, the area of the semiconductor integrated circuit device can be reduced.

The surfaces of the nanosheets 27, 29 that are located on the upper side in the Y direction in the drawing are not exposed from the gate line 36. The surfaces of the nanosheets 28, 30 that are located on the upper side in the Y direction in the drawing are not exposed from the gate line 37. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d3 from the lower end of the active region 2P3 (2N3) in the Y direction in the drawing to the lower end of the cell frame in the Y direction in the drawing is smaller than the distance d4 from the upper end of the active region 2P3 (2N3) in the Y direction in the drawing to the upper end of the cell frame in the Y direction in the drawing. In other words, in plan view, the active region 2P3 (2N3) is disposed close to the lower end of the cell frame in the drawing with respect to the center of the cell frame in the Y direction in the drawing. That is, in plan view, the center portion of the active region 2P3 (2N3) in the Y direction in the drawing is located on the lower side in the drawing with respect to the center portion of the cell frame in the Y direction in the drawing.

In plan view, the power supply line 11 is formed at the lower end portion of the cell in the Y direction in the drawing, and is shared with the standard cell disposed on the lower side of the 2-input NOR cell C3 in the Y direction in the drawing. In plan view, the power supply line 12 is formed at the upper end portion of the cell in the Y direction in the drawing, and is shared with the standard cell disposed on the upper side of the 2-input NOR cell C3 in the Y direction in the drawing. Accordingly, by the 2-input NOR cell C3 being disposed in the circuit block of FIG. 1, the power supply lines for supplying the power supply voltages VDD, VSS can be reinforced. Therefore, it is possible to reduce a decrease in the power supply voltage, and also it is possible to reduce occurrence of electromigration due to current concentration.

The via 73 that connects the power supply line 11 and part of the active region 2P3 that serves as the source of the transistor P21 is formed in a region in which the power supply line 11 and the active region 2P3 overlap with each other in plan view. In plan view, the via 73 is disposed close to the upper side in the drawing in the region in which the power supply line 11 and the active region 2P3 overlap with each other in plan view. In other words, in plan view, the distance d5 in the Y direction from the center portion of the via 73 in the drawing to the upper end of the power supply line 11 in the drawing is smaller than the distance d6 in the Y direction from the center portion of the via 73 in the drawing to the lower end of the active region 2P3 in the drawing. Accordingly, the via 73 is disposed close to the center portion of the active region 2P3 in the Y direction in the drawing, and therefore the difference is reduced between the resistance value from the via 73 to the upper end of the nanosheet 27 of the transistor P21 in the active region 2P3 in the drawing and the resistance value from the via 73 to the lower end of the nanosheet 27 of the transistor P21 in the active region 2P3 in the drawing. Therefore, the current flowing through the transistor P21 is equalized in the Y direction, or in the up-down direction in the drawing, and thus it is possible to increase the speed of the semiconductor integrated circuit device.

Through the via 74 and the local line 45, the power supply line 12 is connected with part of the active region 2N3 that serves as the source of the transistors N21, N22. The length of the via 74 is longer in the Z direction because the via 74 connects the power supply line 12 formed in the BM0 wiring layer and the local line 45 formed in the cell upper portion. As described above, the distance d3 from the lower end of the active region 2P3 (2N3) in the Y direction in the drawing to the lower end of the cell frame in the Y direction in the drawing is smaller than the distance d4 from the upper end of the active region 2P3 (2N3) in the Y direction in the drawing to the upper end of the cell frame in the Y direction in the drawing. Accordingly, it is possible to expand the area from the upper end of the active region 2P3 (2N3) in the Y direction in the drawing to the upper end of the cell frame in the Y direction in the drawing, and therefore the via 74 can be easily formed in that region. Therefore, the semiconductor integrated circuit device can be easily manufactured, and the yield and reliability can be improved.

The via 74 is formed in a region in which the power supply line 12 and the local line 45 overlap with each other in plan view. In plan view, the via 74 is disposed close to the lower side in the drawing in the region in which the power supply line 12 and the local line 45 overlap with each other in plan view. In other words, in plan view, the distance d7 in the Y direction from a center portion of the via 74 in the drawing to the lower end of the power supply line 12 in the drawing is smaller than the distance d8 in the Y direction from the center portion of the via 74 in the drawing to the upper end of the local line 45 in the drawing. Accordingly, the via 74 is disposed even closer to the active region 2N3. Therefore, it is possible to reduce a resistance value from the power supply line 12 to part of the active region 2N3 that serves as the source of the transistor N11, N22, and thus it is possible to increase the speed of the semiconductor integrated circuit device.

The via 75 (79) that connects the line 51 (53) and the gate line 36 (37) is formed in a region to overlap with the active region 2N3 and the gate line 36 (37) in plan view. Accordingly, it is possible to shorten the distance from the line 51 (53) (the input A (the input B)) to part of the gate line 36 (37) overlapping with the nanosheets 27, 29 (28, 30) in plan view that covers the nanosheets 27, 29 (28, 30). Therefore, it is possible to reduce a resistance value from the line 51 (53), and thus it is possible to increase the speed of the semiconductor integrated circuit device.

The line 52 is disposed on the upper side in the Y direction in the drawing with respect to the lines 51, 53 (the side on which the nanosheets 29, 30 are not exposed from the gate lines 36, 37 and which is opposite to the side on which the active region 2N3 is disposed close to the cell frame). The via 76 connects the line 52 and the local line connected to part of the active region 2N3 that serves as the drain of the transistor N21. The via 77 connects the line 52 and the local line connected to part of the active region 2N3 that serves as the drain of the transistor N22. The via 78 connects the local line connected to part of the active region 2N3 that serves as the drain of the transistor N22 and the local line connected to part of the active region 2P3 that serves as the drain of the transistor P22. In plan view, the vias 76 to 78 are formed on the upper side in the Y direction in the drawing with respect to the lines 51, 53. Accordingly, it is possible to shorten the distance from the line 52 to part of the active region 2P3 that serves as the drain of the transistor P22 and the distance from the line 52 to part of the active region 2N3 that serves as the drain of the transistor N21, N22. Therefore, it is possible to reduce a resistance value from the line 52 to part of the active region 2P3 (2N3) that serves as the drain of the transistor P22 (N21, N22), and thus it is possible to increase the speed of the semiconductor integrated circuit device.

### Configuration of 2-Input NOR Cell C6

The 2-input NOR cell C6 and the 2-input NOR cell C3 have substantially the same configuration. Specifically, the 2-input NOR cell C6 has the P-type transistors P21, P22 and the N-type transistors N21, N22, and forms a NOR circuit with the inputs A, B and the output Y.

As shown in FIGS. 8(c) and 8(d), the 2-input NOR cell C6 has an active region 2P6, 2N6 which is different in width in the Y direction from the active region 2P3, 2N3 in the 2-input NOR cell C3 shown in FIGS. 8(a) and 8(b).

Specifically, the width of the active region 2P6, 2N6 in the Y direction is w2. The width w2 is smaller than the width w1. That is, the drive capability of the 2-input NOR cell C3 is greater than the drive capability of the 2-input NOR cell C6.

As shown in FIG. 8, the lower end of the active region 2P6 (2N6) in the Y direction in the drawing is disposed at the same position in the Y direction as the lower end of the active region 2P3 (2N3) in the Y direction in the drawing. That is, the lower end of the active region 2P3 (2N3) of the 2-input NOR cell C3 in the Y direction in the drawing and the lower end of the active region 2P6 (2N6) of the 2-input NOR cell C6 in the Y direction in the drawing are aligned in the Y direction. In the 2-input NOR cell C3, C6, the lower surface of the nanosheets 27 (29) in the Y direction in the drawing is exposed from the gate line 36. In the 2-input NOR cell C3, C6, the lower surface of the nanosheets 28 (30) in the Y direction in the drawing is exposed from the gate line 37. That is, in the 2-input NOR cells C3, C6, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two 2-input NOR cells of which the active regions are different in width are disposed in the circuit block, but three or more 2-input NOR cells of which the active regions are different in width may be disposed in the circuit block. In this case, in each 2-input NOR cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

In the above embodiments and variations, each transistor includes three nanosheets, but some or all of the transistors may include one nanosheet, two nanosheets, four nanosheets, or more nanosheets.

In the above embodiments and variations, the cross-sectional shape of the nanosheet is rectangular, but is not limited to this shape. For example, the shape may be square, circular or elliptical.

In the above embodiments and variations, the P-type transistor is formed in the cell lower portion, and the N-type transistor is formed in the cell upper portion. Alternatively, the P-type transistor may be formed in the cell upper portion, and the N-type transistor may be formed in the cell lower portion.

In the above embodiments and variations, the power supply lines 11, 12 formed in the BM0 wiring layer have the same line width, but the power supply lines 11, 51 may have different line widths.

In the 2-input NAND cells C2, C5, a via similar to the via 61a (62a) shown in FIG. 6, the length of which is greater in the Y direction than in the X direction, may be used instead of the vias 66, 67 (68). Similarly, in the 2-input NOR cells C3, C6, a via similar to the via 61a (62a) shown in FIG. 6, the length of which is greater in the Y direction than in the X direction, may be used instead of the via 73 (74).

Regarding a standard cell using a CFET, the present disclosure provides the layout of a semiconductor integrated circuit device including a standard cell using a forksheet transistor as a transistor, where it is possible to reduce a decrease in the power supply voltage, and also it is possible to reduce occurrence of electromigration due to current concentration.

What is claimed is:

1. A semiconductor integrated circuit device comprising: a plurality of standard cells including a first standard cell, wherein
the first standard cell includes
a first active region forming a channel, a source, and a drain of a first transistor of a first conductivity type and including a first nanosheet extending in a first direction as the channel,
a second active region formed above the first active region in a depth direction; overlapping with the first active region in plan view; forming a channel, a source, and a drain of a second transistor of a second conductivity type different from the first conductivity type; and including a second nanosheet extending in the first direction as the channel,
a first gate line extending in a second direction perpendicular to the first direction and the depth direction and surrounding outer peripheries of the first nanosheet and the second nanosheet in the second direction and the depth direction,
a first power supply line formed on a back surface side of the first transistor; extending in the first direction; and supplying a first power supply voltage, and
a second power supply line formed on the back surface side of the first transistor; extending in the first direction; and supplying a second power supply voltage different from the first power supply voltage,
a surface of each of the first nanosheet and the second nanosheet that is located on a first side which is one side in the second direction is exposed from the first gate line,
the first power supply line is disposed at an end portion of the first standard cell that is located on the first side, and
the second power supply line is disposed at an end portion of the first standard cell that is located on a second side which is the other side in the second direction.

2. The semiconductor integrated circuit device of claim 1, wherein
the plurality of standard cells include a second standard cell adjacent to part of the first standard cell that is located on the first side, and
the first power supply line is shared by the first standard cell and the second standard cell.

3. The semiconductor integrated circuit device of claim 1, wherein
the plurality of standard cells include a third standard cell adjacent to part of the first standard cell that is located on the second side, and
the second power supply line is shared by the first standard cell and the third standard cell.

4. The semiconductor integrated circuit device of claim 1, wherein
the first standard cell further includes a first via formed in a region in which part of the first active region that serves as the source of the first transistor and the first power supply line overlap with each other, and connecting the part of the first active region that serves as the source of the first transistor and the first power supply line.

5. The semiconductor integrated circuit device of claim 4, wherein
in plan view, a distance from a center portion of the first via in the second direction to an end portion of the first power supply line that is located on the second side is smaller than a distance from the center portion of the first via in the second direction to an end portion of the first active region that is located on the first side.

6. The semiconductor integrated circuit device of claim 4, wherein
a length of the first via in the second direction is longer than a length of the first via in the first direction.

7. The semiconductor integrated circuit device of claim 1, wherein
the first standard cell further includes
a first line connected with part of the second active region that serves as the source of the second transistor, and
a second via formed in a region in which the first line and the second power supply line overlap with each other in plan view and connecting the first line and the second power supply line.

8. The semiconductor integrated circuit device of claim 7, wherein
in plan view, a distance from a center portion of the second via in the second direction to an end portion of the second power supply line that is located on the first side is smaller than a distance from the center portion of the second via in the second direction to an end portion of the first line that is located on the second side.

9. The semiconductor integrated circuit device of claim 7, wherein
a length of the second via in the second direction is longer than a length of the second via in the first direction.

10. The semiconductor integrated circuit device of claim 1, wherein
a distance from an end portion of the first active region that is located on the first side to the end portion of the first standard cell that is located on the first side is smaller than a distance from an end portion of the first active region that is located on the second side to an end portion of the first standard cell that is located on the second side.

11. The semiconductor integrated circuit device of claim 1, wherein
the plurality of standard cells include a second standard cell adjacent to part of the first standard cell that is located on the first side, and a third standard cell adjacent to part of the first standard cell that is located on the second side,
the second standard cell includes
a third active region forming a channel, a source, and a drain of a third transistor of the first conductivity type and including a third nanosheet extending in the first direction as the channel, and
a third gate line extending in the second direction and surrounding an outer periphery of the third nanosheet in the second direction and the depth direction,
the third standard cell includes
a fourth active region forming a channel, a source, and a drain of a fourth transistor of the first conductivity type and including a fourth nanosheet extending in the first direction as the channel, and
a fourth gate line extending in the second direction and surrounding an outer periphery of the fourth nanosheet in the second direction and the depth direction,
a surface of the third nanosheet that is located on the second side is exposed from the third gate line,
a surface of the fourth nanosheet that is located on the second side is exposed from the fourth gate line, and
a distance in the second direction between the first active region and the third active region is smaller than a distance in the second direction between the first active region and the fourth active region.

12. The semiconductor integrated circuit device of claim 1, wherein
the first active region forms a channel, a source, and a drain of a fifth transistor of the first conductivity type, and includes a fifth nanosheet extending in the first direction as the channel,
the second active region forms a channel, a source, and a drain of a sixth transistor of the second conductivity type, and includes a sixth nanosheet extending in the first direction as the channel,
the first standard cell includes a second gate line extending in the second direction and surrounding outer peripheries of the fifth nanosheet and the sixth nanosheet in the second direction and the depth direction, and
a surface of each of the fifth nanosheet and the sixth nanosheet that is located on the first side is exposed from the second gate line.

13. The semiconductor integrated circuit device of claim 1, wherein
the plurality of standard cells include a fourth standard cell with which the first standard cell is arranged in the first direction,
the fourth standard cell includes
a seventh active region forming a channel, a source, and a drain of a seventh transistor of the first conductivity type and including a seventh nanosheet extending in the first direction as the channel,
an eighth active region formed above the seventh active region in the depth direction; overlapping with the seventh active region in plan view; forming a channel, a source, and a drain of an eighth transistor of the second conductivity type; and including an eighth nanosheet extending in the first direction as the channel, and
a fifth gate line extending in the second direction and surrounding outer peripheries of the seventh nanosheet and the eighth nanosheet in the second direction and the depth direction,
a surface of each of the seventh nanosheet and the eighth nanosheet that is located on the first side is exposed from the fifth gate line,
in plan view, a width of the seventh nanosheet in the second direction is smaller than a width of the first nanosheet in the second direction, and
in plan view, an end portion of the first nanosheet that is located on the first side and an end portion of the seventh nanosheet that is located on the first side are disposed at the same position in the second direction.
